(19) United States
(12) Patent Application Publication
(10) Pub. No.: US 2022/0349064 A1
(43) Pub. Date: Nov. 3, 2022

(54) ETCHANT AND ETCHING METHOD FOR COPPER-MOLYBDENUM FILM LAYER

(71) Applicant: TCL China Star Optoelectronics Technology Co., Ltd., Shenzhen, Guangdong (CN)

(72) Inventors: Yuehong ZHANG, Shenzhen, Guangdong (CN); Yifeng HE, Shenzhen, Guangdong (CN)

(73) Assignee: TCL China Star Optoelectronics Technology Co., Ltd., Shenzhen, Guangdong (CN)

(21) Appl. No.: 17/600,169

(22) PCT Filed: Dec. 29, 2020
(86) PCT No.: PCT/CN2020/140637

§ 371 Date: Sep. 30, 2021

(30) Foreign Application Priority Data
Nov. 9, 2020 (CN) 202011237543.7

(51) Int. Cl. C23F 1/18; C23F 1/26; C23F 1/02

(52) U.S. Cl. CPC C23F 1/18; C23F 1/26; C23F 1/02

(57) ABSTRACT

The present invention discloses an etchant and an etching method for a copper-molybdenum film layer. The etchant includes a main etchant, and the main etchant includes hydrogen peroxide, a chelating agent, a first inorganic acid, and water. A mass percentage of the chelating agent in the main etchant is in a range of 2% to 10%, a mass percentage of the first inorganic acid in the main etchant is in a range of 1% to 10%, and a mass percentage of the hydrogen peroxide in the main etchant is in a range of 4% to 10%.

### FIELD OF INVENTION

The present invention relates to the field of display technologies, and specifically, to an etchant and an etching method for a copper-molybdenum film layer.

### BACKGROUND OF INVENTION

Based on requirements for large displays and high-definition picture quality, an electrical signal transmission wire requires a metal material having a lower electrical resistivity. At present, copper is widely used for preparation of large-size displays by virtue of a relatively high conductivity and a relatively low price. However, adhesion of a copper film layer to a glass substrate is poor, and copper atoms are likely to diffuse into a silicon oxide film or a silicon nitride film. Therefore, a thin buffering layer is added between the copper film layer and the glass. Molybdenum or molybdenum alloy is usually used to form a copper-molybdenum-laminated film layer.

If a same etchant is used to simultaneously etch a copper film layer and a molybdenum film layer in the copper-molybdenum-laminated film layer having different chemical properties, an undesirable phenomenon, such as an undesirable etching taper angle or molybdenum undercut between two film layers is likely to occur. In order to alleviate the undesirable phenomenon, additives containing fluorions, such as hydrofluoric acid and ammonium fluoride are usually added to the etchant, which, however, results in the following disadvantages. Firstly, a fluorine-containing etching waste liquid requires high treatment costs and is unfriendly to the environment. Secondly, the etchant contains fluorions, which are likely to cause health hazards to operators, or even cause industrial safety accidents. In addition, the fluorions corrode the glass substrate to a specific extent, which is likely to cause damage to the glass substrate. Thus, it is urgent to develop an etchant for the copper-molybdenum-laminated film layer, so as to obtain a more desirable etching effect.

### SUMMARY OF INVENTION

### Technical Problem

The present invention provides an etchant and an etching method for a copper-molybdenum film layer, which can achieve a relatively desirable etching effect.

### Technical Solutions

In order to resolve the above problems, in a first aspect, the present invention provides an etchant for a copper-molybdenum film layer. The etchant includes a main etchant, and the main etchant includes hydrogen peroxide, a chelating agent, a first inorganic acid, and water, A mass percentage of the chelating agent in the main etchant is in a range of 2% to 10%, a mass percentage of the first inorganic acid in the main etchant is in a range of 1% to 10%, and a mass percentage of the hydrogen peroxide in the main etchant is in a range of 4% to 10%.

In order to resolve the above problems, in a second aspect, the present invention provides an etching method for a copper-molybdenum film layer. The method includes:

providing a substrate, wherein a copper-molybdenum film layer is formed on the substrate, a patterned photoresist layer is formed on the copper-molybdenum film layer, and the copper-molybdenum film layer includes a molybdenum film layer and a copper film layer disposed on a side of the molybdenum film layer that faces away from the substrate;

providing a main etchant, and etching, using the main etchant, the copper-molybdenum film layer shielded by the patterned photoresist layer, wherein the main etchant includes hydrogen peroxide, a chelating agent, a first inorganic acid, and water, a mass percentage of the chelating agent in the main etchant is in a range of 2% to 10%, a mass percentage of the first inorganic acid in the main etchant is in a range of 1% to 10%, and a mass percentage of the hydrogen peroxide in the main etchant is in a range of 4% to 10%; and

peeling off the patterned photoresist layer.

### Beneficial Effects

Beneficial effects are as follows: The present invention provides an etchant and an etching method for a copper-molybdenum film layer. The etchant includes a main etchant, and the main etchant includes hydrogen peroxide, a chelating agent, a first inorganic acid, and water. The mass percentage of the chelating agent in the main etchant is in a range of 2% to 10%, and the mass percentage of the inorganic acid in the main etchant is in a range of 1% to 10%. By adjusting the percentages of the chelating agent and the inorganic acid, a relatively small etching taper angle can be obtained, thereby satisfying a requirement for a higher contrast of a display panel. In addition, film layer undercut or a molybdenum residue that is likely to cause undesirability of the display panel is avoided.

### BRIEF DESCRIPTION OF DRAWINGS

FIG. 1 is a microscopic topography of an etched copper-molybdenum film layer having molybdenum undercut presented in a scanning electron microscope in the conventional technology.

FIG. 2 is a microscopic topography of an etched copper-molybdenum film layer having molybdenum residues presented in a scanning electron microscope in the conventional technology.

FIG. 3 is a microscopic cross-sectional topography of a film layer 1 after first etching presented in a scanning electron microscope according to an embodiment of the present invention.

FIG. 4 is a microscopic surface topography of a film layer 1 after first etching presented in a scanning electron microscope according to an embodiment of the present invention.

FIG. 5 is a microscopic cross-sectional topography of a film layer 2 after first etching presented in a scanning electron microscope according to an embodiment of the present invention.

FIG. 6 is a microscopic surface topography of a film layer 2 after first etching presented in a scanning electron microscope according to an embodiment of the present invention.

FIG. 7 is a microscopic cross-sectional topography of a film layer 1 after second etching presented in a scanning electron microscope according to an embodiment of the present invention.

FIG. 8 is a microscopic surface topography of a film layer 1 after second etching presented in a scanning electron microscope according to an embodiment of the present invention.

FIG. 9 is a microscopic cross-sectional topography of a film layer 2 after second etching presented in a scanning electron microscope according to an embodiment of the present invention.

FIG. 10 is a microscopic surface topography of a film layer 2 after second etching presented in a scanning electron microscope according to an embodiment of the present invention.

FIG. 11 is a microscopic cross-sectional topography of a film layer 1 after third etching presented in a scanning electron microscope according to an embodiment of the present invention.

FIG. 12 is a microscopic surface topography of a film layer 1 after third etching presented in a scanning electron microscope according to an embodiment of the present invention.

FIG. 13 is a microscopic cross-sectional topography of a film layer 2 after third etching presented in a scanning electron microscope according to an embodiment of the present invention.

FIG. 14 is a microscopic surface topography of a film layer 2 after third etching presented in a scanning electron microscope according to an embodiment of the present invention.

FIG. 15 is a microscopic cross-sectional topography of a film layer 1 after fourth etching presented in a scanning electron microscope according to an embodiment of the present invention.

FIG. 16 is microscopic surface topography of a film layer 1 after fourth etching presented in a scanning electron microscope according to an embodiment of the present invention.

FIG. 17 is a microscopic cross-sectional topography of a film layer 2 after fourth etching presented in a scanning electron microscope according to an embodiment of the present invention.

FIG. 18 is microscopic surface topography of a film layer 2 after fourth etching presented in a scanning electron microscope according to an embodiment of the present invention.

FIG. 19 is a microscopic cross-sectional topography of a film layer 1 after fifth etching presented in a scanning electron microscope according to an embodiment of the present invention.

FIG. 20 is a microscopic surface topography of a film layer 1 after fifth etching presented in a scanning electron microscope according to an embodiment of the present invention.

FIG. 21 is a microscopic cross-sectional topography of a film layer 2 after fifth etching presented in a scanning electron microscope according to an embodiment of the present invention.

FIG. 22 is a microscopic surface topography of a film layer 2 after fifth etching presented in a scanning electron microscope according to an embodiment of the present invention.

### DETAILED DESCRIPTION OF PREFERRED EMBODIMENTS

The technical solutions of the embodiments of the present invention are clearly and completely described in the following with reference to the accompanying drawings of the embodiments of the present invention. Apparently, the described embodiments are merely some but not all of the embodiments of the present invention. All other embodiments obtained by a person skilled in the art based on the embodiments of the present invention without creative efforts shall fall within the protection scope of the present invention.

In the description of the present invention, it should be understood that, orientational or positional relationships indicated by the terms such as “center”, “longitudinal”, “transverse”, “length”, “width”, “thickness”, “up”, “down”, “front”, “back”, “left”, “right”, “vertical”, “horizontal”, “top”, “bottom”, “inner”, and “outer” are orientational or positional relationships shown based on the accompanying drawings, and are merely used for ease of describing the present invention, rather than indicating or implying that the apparatus or element must have a particular orientation or be constructed and operated in a particular orientation, and therefore, should not be construed as a limitation on the present invention. In addition, the terms “first” and “second” are used merely for the purpose of description, and are not to be construed as indicating or implying relative importance or implying the number of technical features indicated. Therefore, a feature limited by “first” or “second” can explicitly or implicitly include one or more said features. In the description of the present invention, “a plurality of” means two or more than two, unless otherwise particularly specified.

In the present invention, the term “exemplary” or “exemplarily” is used for indicating “giving an example, an illustration, or a description”. Any embodiment described as “exemplary” in the present invention is not to be explained as being more preferred or having more advantages than other embodiments. The following descriptions are provided to enable a person skilled in the art to implement and use the present invention. In the following descriptions, details are given for the purpose of explanation. It is to be appreciated by a person skilled in the art that the present invention can also be implemented without using these specific details. In other examples, well-known structures and processes will not be described in detail, so as to prevent the descriptions of the present invention from being obscured by unnecessary details. Therefore, the present invention is not limited to the embodiments shown, but is to be accorded the widest scope consistent with the principles and features disclosed in the present invention.

As described in the background art, in order to satisfy the requirements for large displays and high-definition picture quality, copper having a high conductivity is usually used as a metal wiring material. However, due to a property of copper, adhesion of a copper film layer to a glass substrate is relatively poor. As a result, the film layer can divorce, or copper atoms are likely to diffuse into a silicon oxide film or silicon nitride film, affecting performance of a display panel. A relatively thin molybdenum film layer is usually disposed under the copper film layer as a buffering layer, to overcome the above defects.

However, if a same etchant is used to simultaneously etch the copper film layer and the molybdenum film layer having different chemical properties, the etching is hard to control. As a result, an ideal etching effect is hard to achieve. Details are as follows.

First of all, as displays develop, a display having a high contrast is increasingly popular. When an etching taper angle of a gate electrode in an array substrate decreases by a specific extent, a tail section of the gate electrode is longer, so that more light can be shielded. In this way, light and shade contrast is enhanced, that is, a contrast of the display can be significantly increased. However, with a currently used etchant for a copper-molybdenum film layer, the taper angle can be controlled only between 50 degrees and 60 degrees, failing to satisfy the requirements for a high contrast of displays.

Secondly, due to different chemical properties of copper and molybdenum, an electrode potential of the molybdenum is lower than an electrode potential of the copper in an acid etchant, resulting in an electrode potential difference. As a result, electrochemical corrosion is formed between the copper and the molybdenum in a conductive etchant solution. The molybdenum acts as an anode, and the copper acts as a cathode, accelerating a rate of etching the molybdenum. Finally, when the etching ends, molybdenum undercut occurs. Specifically, as shown in FIG. 1, an obvious small recessed corner exists at an edge of a film layer in a dashed box, which is the molybdenum undercut. The phenomenon degrades reliability of a display panel to a specific extent and is likely to cause poor picture quality, such as a broken-line picture, causing a loss to a product yield.

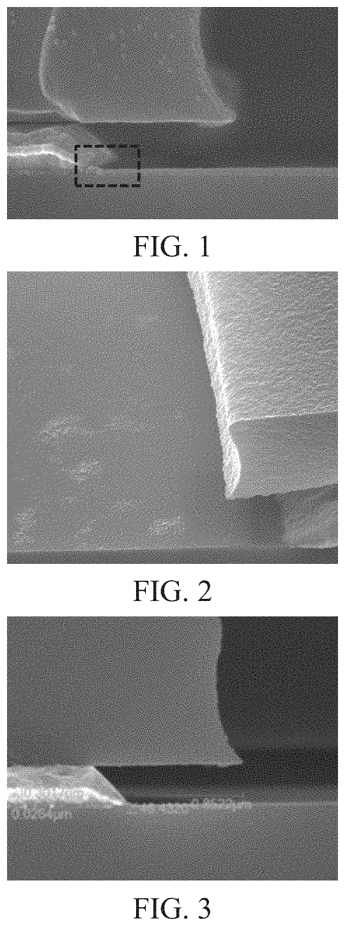

Thirdly, the molybdenum is oxidized into molybdenum dioxide or molybdenum pentoxide by hydrogen peroxide in the acid etchant. A detailed reaction principle is shown in the following equation (1). The two oxides have poor solubility in the etchant, and therefore remain on the glass substrate, forming molybdenum residues. Specifically, as shown in FIG. 2, an obvious white agglomerate foreign matter can be observed on a surface. It is learned by means of elemental analysis that the foreign matter mainly includes a molybdenum element and an oxygen element, which are the above oxides of the molybdenum. If the molybdenum oxide adheres to the surface of the substrate, a short circuit can occur between metal wires in a thin film transistor device, resulting in an abnormal picture.

Mo+2H₂O₂═MoO₂2H₂O

2MoO₂+H₂O₂=Mo₂O₅+H₂O Equation (1)

A conventional solution for the phenomenon is to add a specific amount of a fluorine-containing additives, such as hydrofluoric acid or ammonium fluoride. However, the fluorine-containing additives bring some disadvantages. Firstly, a fluorine-containing etching waste liquid requires high treatment costs and is unfriendly to the environment. Secondly, the etchant contains fluorions, which are likely to cause health hazards to operators, or even cause industrial safety accidents. In addition, the fluorions corrode the glass substrate to a specific extent, which is likely to cause damage to the glass substrate.

In addition to the poor etching effect, a copper-molybdenum etchant has a short service life. Reasons are as follows. As etching progresses, a concentration of copper ions in the etchant increases. When the concentration of the copper ions reaches a specific extent, a main etching component in the etchant, that is, the hydrogen peroxide is catalyzed by the copper ions to acutely decompose, generating a large amount of hydrogen. The hydrogen leads to a relatively severe potential safety hazard, or even leads to an explosion. In addition, at a high concentration of copper ions, contents of effective components in the copper-molybdenum etchant change, which causes a change in etching characteristics, resulting in abnormal products. Based on the above reasons, the copper-molybdenum etchant has a short service life, requires high manufacturing costs, and pollutes the environment as a result of increased waste discharging. Thus, prolonging the service life of the etchant is extremely important for cost reduction and environment protection.

Based on the above problems, an embodiment of the present invention provides an etchant for a copper-molybdenum film layer. The etchant includes a main etchant, and the main etchant includes hydrogen peroxide, a chelating agent, a first inorganic acid, and water. A mass percentage of the chelating agent in the main etchant is in a range of 2% to 10%, and further preferably, in a range of 4% to 6%. A mass percentage of the first inorganic acid in the main etchant is in a range of 1% to 10%, and further preferably, in a range of 1% to 4%. The mass percentage of the hydrogen peroxide in the main etchant is in a range of 4% to 10%, and further preferably, in a range of 6% to 9%.

In the etchant provided in the present embodiment, the hydrogen peroxide is a main etching component, and can react with copper and molybdenum in an acid environment to achieve etching, and the chelating agent and the inorganic acid of specific percentages are added, to achieve relatively desirable etching characteristics.

Specifically, the chelating agent is mainly used to chelate, using a specific functional group in a structure of the chelating agent, metal ions in the etchant, that is, copper ions and molybdenum ions in the etchant that are formed by means of etching, to reduce a concentration of free metal ions in an etching system, so as to inhibit a catalytic action of the metal ions, especially the copper ions, on decomposition of the hydrogen peroxide, thereby maintaining stability of the etching system. The first inorganic acid provides an acid environment required for the etching. More importantly, since an electrode potential difference between the copper and the molybdenum in the acid etchant vary in solutions having different pH values, the electrode potential difference between the copper and the molybdenum can be controlled by adjusting the content of the inorganic acid, to control a ratio of rates of etching a copper film layer and a molybdenum film layer, so as to obtain a relatively small taper angle and avoid molybdenum undercut or molybdenum residues

That is, by adjusting the contents of the chelating agent and the first inorganic acid, the etching system is maintained stable and required etching characteristics are obtained.

In some embodiments, the first inorganic acid can be selected from common inorganic acid, such as sulfuric acid, nitric acid, phosphoric acid, and hydrochloric acid, which is not particularly limited in the present invention.

In some embodiments, the chelating agent is a first organic acid, which is a carboxylic acid compound. A carboxyl group included therein can achieve a strong chelating effect, and can help the inorganic acid adjust a pH value of the etching system. The carboxylic acid compound can be selected from one or more of imino acetic acid, ethylenediaminetetraacetic acid, citric acid, malic acid, acetic acid, succinic acid, tartaric acid, gluconic acid, and hydroxyacetic acid. Certainly, the carboxylic acid compound can also be any other common carboxylic acid, which is not enumerated herein.

Further, a pH value of the etchant is adjusted to a range of 4-5 to obtain optimal etching characteristics.

In some embodiments, the main etchant further includes a buffering agent and a stabilizing agent. A mass percentage of the buffering agent in the main etchant is in a range of 0.5% to 5%, and further preferably, in a range of 0.5% to 2%. A mass percentage of the stabilizing agent in the main etchant is in a range of 0.5% to 5%, and further preferably, in a range of 0.5% to 2%.

The buffering agent is a pH buffering agent, and is mainly used to avoid a large fluctuation of the pH of the etching system and abnormal etching, facilitating enhancement of stability of the etching process. Detailed components of the buffering agent are not particularly limited. A buffering agent of a PH frequently used in the art, such as salt of weak acid or salt of weak acid and strong base can be selected. Exemplarily, the buffering agent can include at least one of acetic acid, sodium acetate, sodium hydrogen phosphate, and sodium borate.

The stabilizing agent usually also includes a functional group (such as carboxyl, silicate, or phosphate) used for chelating, and helps the chelating agent realize chelating of metal ions. In addition, the molecule further includes atoms (such as nitrogen and oxygen) having strong electronegativity, which can quench hydroxyl radicals generated during decomposition of the hydrogen peroxide, and reduce a decomposition rate of the hydrogen peroxide. In this way, the stability of the etching system is further maintained. The stabilizing agent is a compound including the above functional group and elements. Exemplarily, the stabilizing agent includes at least one of diethylamine pentaacetic acid, sodium silicate, magnesium chloride, tartaric acid, and trisodium phosphate.

In some embodiments, an etchant further includes an auxiliary etchant. Specifically, the auxiliary etchant includes second organic acid and/or second inorganic acid, an inhibitor, and water. A mass percentage of the second organic acid and/or the second inorganic acid in the auxiliary etchant is in a range of 0% to 20%, and further preferably, in a range of 4% to 10%. A mass percentage of the inhibitor in the auxiliary etchant is in a range of 2% to 5%, and further preferably, in a range of 3% to 4%.

Detailed components of the second organic acid can be same as or different from the detailed components of the first organic acid in the main etchant that is used as the chelating agent. Detailed components of the second inorganic acid can be same as or different from the detailed components of the first inorganic acid in the main etchant that is used as the chelating agent. According to actual process requirements, the auxiliary etchant can include only the organic acid or only the second organic acid, or can include both of the organic acid and the second organic acid.

The inhibitor is an azole compound (a compound including a heteronitrogen five membered ring structure), such as substituted or unsubstituted triazole, substituted or unsubstituted benzotriazole, substituted or unsubstituted imidazole, substituted or unsubstituted benzimidazole, substituted or unsubstituted pyrazol, substituted or unsubstituted benzopyrazole, substituted or unsubstituted thiazole, or substituted or unsubstituted benzothiazole. It should be noted that, the expression “substituted” herein means substituting at least one hydrogen with hydroxyl, amino, phenyl, biphenyl, naphthyl, or alkyl having 1-5 carbon atoms. For example, the inhibitor can be selected from at least one of benzotriazole, hydroxybenzotriazole, methyl benzotriazole, aminotriazole, thiazole, and phenylthiazole.

In the above azole compound, nitrogen atoms in the heteronitrogen ring have a strong electron donating ability, which can provide electrons to metal atoms, so that the atoms are adsorbed on a metal film layer to form a barrier film, thereby reducing an etching rate. However, based on different properties of the copper and the molybdenum, the reduction also varies for the copper film layer and the molybdenum film layer. On this basis, the inhibitor having a specific structure is added, to optimize the etching taper angle.

It should be supplemented that, the auxiliary etchant is added when the concentration of the copper ions in the etchant reaches a threshold, to supplement necessary components required in the etchant and provide a dilution effect to properly reduce the concentration of the copper ions in the etching system, so that the etchant can still perform etching stably and effectively, thereby prolonging a service life of the copper-molybdenum etchant composition. Generally, the service life of the copper-molybdenum etchant composition can be prolonged to at least 8000 ppm (in the present invention, the concentration of the copper ions defines the service life of the etchant for the copper-molybdenum film layer).

It should be supplemented that, the water in the copper-molybdenum etchant composition is deionized water, to avoid introducing heteroions and degrading the stability of the etching effect of the copper-molybdenum etchant composition.

In addition, in addition to the necessary components described in the above embodiments, the main etchant and the auxiliary etchant can further include any other component according to actual process requirements, which is not limited in the present invention.

In another embodiment of the present invention, an etching method for a copper-molybdenum film layer is further provided. The etching method includes performing etching by using the etchant for a copper-molybdenum film layer provided in the above embodiments, and specifically includes steps of:

providing a substrate, wherein a copper-molybdenum film layer is formed on the substrate, a patterned photoresist layer is formed on the copper-molybdenum film layer, and the copper-molybdenum film layer includes a molybdenum film layer and a copper film layer disposed on a side of the molybdenum film layer that faces away from the substrate;

providing a main etchant, and etching, using the main etchant, the copper-molybdenum film layer shielded by the patterned photoresist layer, wherein the main etchant includes hydrogen peroxide, a chelating agent, a first inorganic acid, and water, a mass percentage of the chelating agent in the main etchant is in a range of 2% to 10%, a mass percentage of the first inorganic acid in the main etchant is in a range of 1% to 10%, and a mass percentage of the hydrogen peroxide in the main etchant is in a range of 4% to 10%; and

peeling off the patterned photoresist layer to finish etching and form a patterned copper-molybdenum film layer.

In some embodiments, the chelating agent is a first organic acid, and a pH value of the etchant is in a range of 4-5.

In some embodiments, the main etchant further includes a buffering agent and a stabilizing agent. A mass percentage of the buffering agent in the main etchant is in a range of 0.5% to 5%, and a mass percentage of the stabilizing agent in the main etchant is in a range of 0.5% to 5%.

In some embodiments, the buffering agent includes at least one of acetic acid, sodium acetate, sodium hydrogen phosphate, and sodium borate, and the stabilizing agent includes at least one of diethylamine pentaacetic acid, sodium silicate, magnesium chloride, tartaric acid, and trisodium phosphate.

In some embodiments, the step of etching, using the main etchant, the copper-molybdenum film layer shielded by the patterned photoresist layer further includes steps of:

continuously detecting a content of copper ions in the main etchant; and

adding an auxiliary etchant to the main etchant when the content of the copper ions in the main etchant reaches a threshold. The auxiliary etchant includes: second organic acid and/or second inorganic acid, an inhibitor, and water. A mass percentage of the second organic acid and/or the second inorganic acid in the auxiliary etchant is in a range of 0% to 20%, a mass percentage of the inhibitor in the auxiliary etchant is in a range of 2% to 5%, and a mass of the added auxiliary etchant is in a range of 4% to 10% of a mass of the etchant before the addition.

In some embodiments, an inhibitor is selected from at least one of substituted or unsubstituted triazole, substituted or unsubstituted benzotriazole, substituted or unsubstituted imidazole, substituted or unsubstituted benzimidazole, substituted or unsubstituted pyrazol, substituted or unsubstituted benzopyrazole, substituted or unsubstituted thiazole, and substituted or unsubstituted benzothiazole.

Specifically, at an initial phase of etching the copper-molybdenum film layer using the etchant, the etchant includes only the main etchant. As the etching progresses, the content of the copper ions in the main etchant increases accordingly. When the content of the copper ions in the main etchant reaches a predetermined threshold, the auxiliary etchant is added to maintain the stability of the etching.

A mass of the added auxiliary etchant is in a range of 4% to 10% of a total mass of the etchant before the addition. The amount of the added auxiliary etchant herein should not be excessively small. Otherwise, an adjustment effect is not obvious. In addition, the amount of the added auxiliary etchant should not be excessively large. Otherwise, a large fluctuation occurs in the etching effect as a result of a large difference between the components of the etchant before and after the addition.

A moment for adding the auxiliary etchant is determined according to actual process requirements. The auxiliary etchant can be added only once or a plurality of times. The moment for adding the auxiliary etchant is determined according to the content of the copper ions in the etchant. The content of the copper ions in the etchant during the addition of the auxiliary etchant is defined as a threshold.

If the auxiliary etchant is added at least three times, there are at least three sub-thresholds correspondingly. In a first detailed implementation, the at least three sub-thresholds are arranged in an arithmetic sequence. In a second detailed implementation, since control on the stability of the etching degrades with the increasing concentration of the copper ions of the etchant, the auxiliary etchant requires to be added more times over time the etchant is used. That is, differences between adjacent ones of the at least three sub-thresholds in ascending order decrement.

In some embodiments, after the content of the copper ions of the etchant reaches a specific extent, the stability of the etching is hard to maintain merely by adding the auxiliary etchant. Thus, when the content of the copper ions of the etchant reaches a second threshold, not only a specific amount of auxiliary etchants are added, but also a specific amount of main etchants are added, so as to further prolong the service life of the etchant. The second threshold is greater than the above threshold, and includes one or more second sub-thresholds.

Further, in some embodiments, when the content of the copper ions of the etchant reaches the second threshold, part of the original etchant can be discharged while a specific amount of main etchants of the auxiliary etchant are added, to further optimize the composition of the etchant, thereby prolonging the service life of the etchant.

Detailed embodiments are provided below for further illustration.

An etchant for a copper-molybdenum film layer is provided. The etchant includes a main etchant and an auxiliary etchant. Detailed compositions are shown in Table 1:

TABLE 1

| Main etchant | | Auxiliary etchant | |
|---|---|---|---|
| Component | Content/wt % | Component | Content/wt % |
| Hydrogen peroxide | 8 | Citric acid | 6 |
| Iminodiacetic acid | 6 | Benzotriazole | 2.5 |
| Phosphoric acid | 2 | Deionized water | 91.5 |
| Acetic acid | 1 | | |
| Diethylamine | 1 | | |
| pentaacetic acid | | | |
| Deionized water | 82 | | |

The auxiliary etchant is added in a proportion of 25 g auxiliary etchant/500 g total current etchant when a content of copper ions in the etchant is 2000 ppm, 4000 ppm, and 6000 ppm.

A first copper-molybdenum film layer (a molybdenum-copper-laminated film layer, having a corresponding thickness of 300/3000 angstroms and referred to as a film layer 1 below) and a second copper-molybdenum film layer (a molybdenum-copper-laminated film layer, having a corresponding thickness of 300/7000 angstroms and referred to as a film layer 2 below) are etched using the etchant provided above. An etching effect is determined when a concentration of copper ions in the etchant is 500 ppm, 2000 ppm (before first addition of the auxiliary etchant), 4000 ppm (before second addition of the auxiliary etchant), 6000 ppm (before third addition of the auxiliary etchant), and 8000 ppm. Specifically, a scanning electron microscope is used to determine a taper angle, a critical dimension loss (CD Loss) compared to a photoresist edge, and whether molybdenum residues and molybdenum undercut exist. Summarized results are shown in Table 2:

TABLE 2

| Service life of | To-be-etched | | |
|---|---|---|---|
| echant/ppm | object | CDLoss/μm | Taper/° |
| 500 | Film layer 1 | 0.85 | 46.4 |
| | Film layer 2 | 0.90 | 43.0 |
| 2000 | Film layer 1 | 0.87 | 38.1 |
| | Film layer 2 | 0.88 | 38.4 |
| 4000 | Film layer 1 | 0.77 | 41.3 |
| | Film layer 2 | 0.83 | 43.9 |
| 6000 | Film layer 1 | 0.76 | 47.5 |
| | Film layer 2 | 0.80 | 41.3 |
| 8000 | Film layer 1 | 0.74 | 40.5 |
| | Film layer 2 | 0.70 | 29.9 |

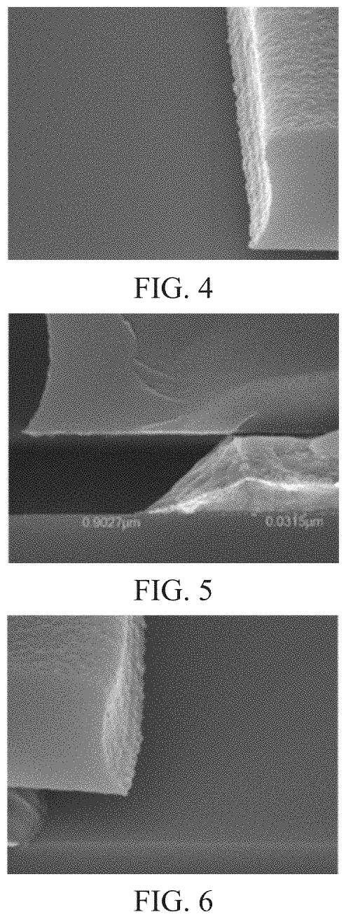

A result of etching the film layer 1 when the service life of the etchant is 500 ppm is shown in a cross-sectional topography phenogram provided in FIG. 3, which shows a taper angle of 46.4° and no molybdenum undercut, and in a topography phenogram in a top view provided in FIG. 4, which shows no molybdenum residues.

A result of etching the film layer 2 when the service life of the etchant is 500 ppm is shown in a cross-sectional topography phenogram provided in FIG. 5, which shows a taper angle of 43.0° and no molybdenum undercut, and in a topography phenogram in a top view provided in FIG. 6, which shows no molybdenum residues.

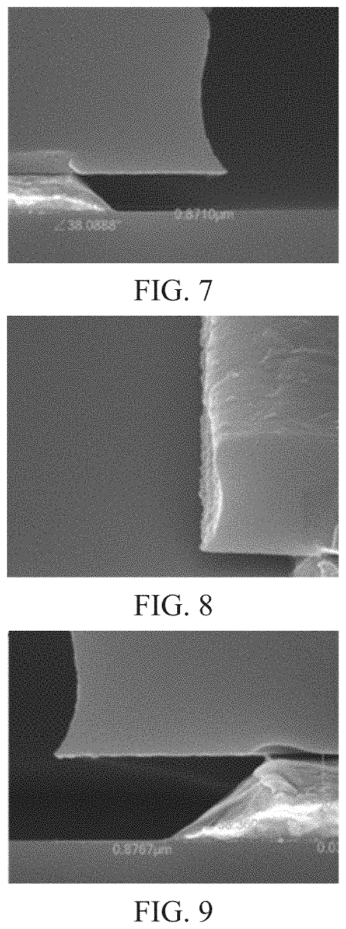

A result of etching the film layer 1 when the service life of the etchant is 2000 ppm is shown in a cross-sectional topography phenogram provided in FIG. 7, which shows a taper angle of 38.1° and no molybdenum undercut, and in a topography phenogram in a top view provided in FIG. 8, which shows no molybdenum residues.

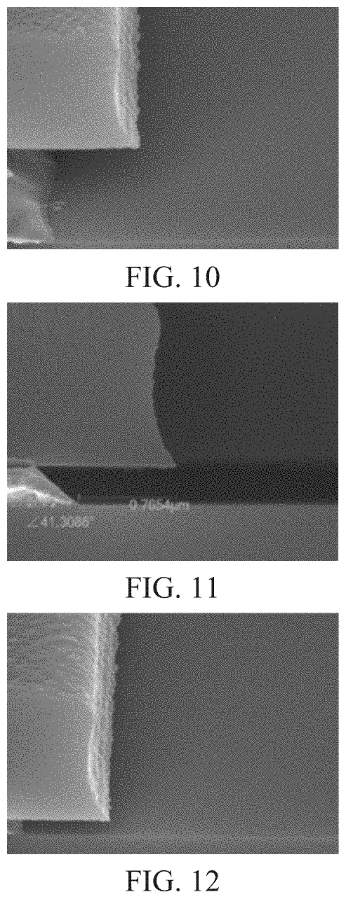

A result of etching the film layer 2 when the service life of the etchant is 2000 ppm is shown in a cross-sectional topography phenogram provided in FIG. 9, which shows a taper angle of 38.4° and no molybdenum undercut, and in a topography phenogram in a top view provided in FIG. 10, which shows no molybdenum residues.

A result of etching the film layer 1 when the service life of the etchant is 4000 ppm is shown in a cross-sectional topography phenogram provided in FIG. 11, which shows a taper angle of 41.3° and no molybdenum undercut, and in a topography phenogram in a top view provided in FIG. 12, which shows no molybdenum residues.

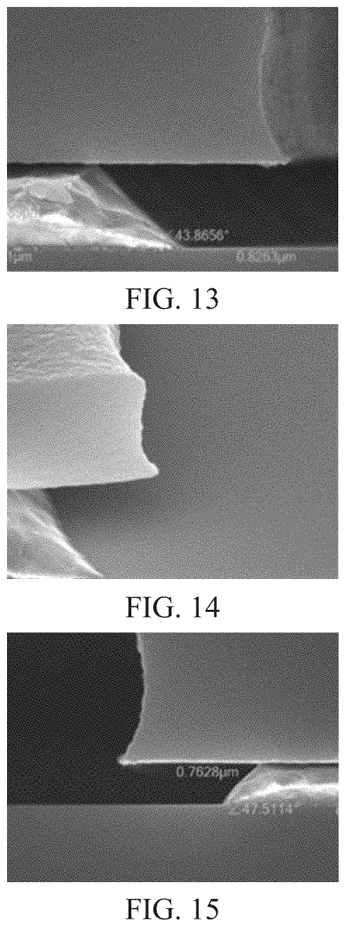

A result of etching the film layer 2 when the service life of the etchant is 4000 ppm is shown in a cross-sectional topography phenogram provided in FIG. 13, which shows a taper angle of 43.9° and no molybdenum undercut, and in a topography phenogram in a top view provided in FIG. 14, which shows no molybdenum residues.

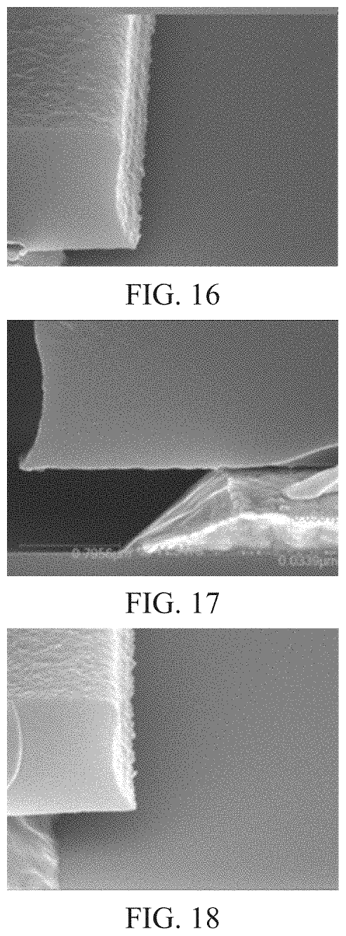

A result of etching the film layer 1 when the service life of the etchant is 6000 ppm is shown in a cross-sectional topography phenogram provided in FIG. 15, which shows a taper angle of 47.5° and no molybdenum undercut, and in a topography phenogram in a top view provided in FIG. 16, which shows no molybdenum residues.

A result of etching the film layer 2 when the service life of the etchant is 6000 ppm is shown in a cross-sectional topography phenogram provided in FIG. 17, which shows a taper angle of 41.3° and no molybdenum undercut, and in a topography phenogram in a top view provided in FIG. 18, which shows no molybdenum residues.

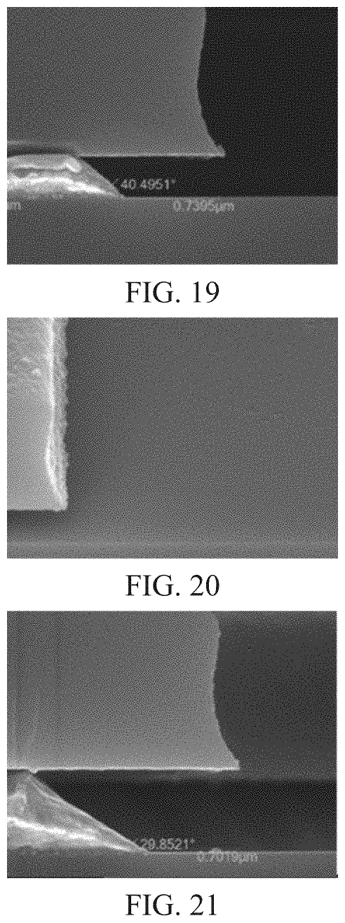

A result of etching the film layer 1 when the service life of the etchant is 8000 ppm is shown in a cross-sectional topography phenogram provided in FIG. 19, which shows a taper angle of 40.5° and no molybdenum undercut, and in a topography phenogram in a top view provided in FIG. 20, which shows no molybdenum residues.

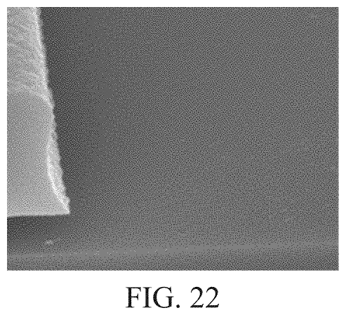

A result of etching the film layer 2 when the service life of the etchant is 8000 ppm is shown in a cross-sectional topography phenogram provided in FIG. 21, which shows a taper angle of 29.9° and no molybdenum undercut, and in a topography phenogram in a top view provided in FIG. 22, which shows no molybdenum residues.

In addition, CD losses in the above cases conform to a control specification of 0.8+/−0.2 μm, so that no other undesirability is caused.

In conclusion, etching the copper-molybdenum film layer using the etchant provided in the present invention can obtain relatively small taper angles that are less than 50°, satisfying requirements for a high contrast, and can eliminate molybdenum undercut and molybdenum residues that are likely to cause undesirability, satisfying requirements for etching film layers having different thicknesses.

In the foregoing embodiments, the descriptions of the embodiments have respective focuses. For a part that is not described in detail in an embodiment, reference can be made to the detailed description of other embodiments provided above, and the details will not be described herein again.

An etchant and an etching method for a copper-molybdenum film layer provided in the embodiments of the present invention have been described in detail above. Although the principles and implementations of the present invention are described by using specific examples in this specification, the descriptions of the foregoing embodiments are merely used for helping understand the method and the core idea of the present invention. Meanwhile, a person skilled in the art can make modifications to the specific implementations and application range according to the idea of the present invention. In conclusion, the content of this specification is not to be construed as a limitation to the present invention.

What is claimed is:

1. An etchant for a copper-molybdenum film layer, wherein the etchant comprises a main etchant, and the main etchant comprises hydrogen peroxide, a chelating agent, a first inorganic acid, and water, a mass percentage of the chelating agent in the main etchant is in a range of 2% to 10%, a mass percentage of the first inorganic acid in the main etchant is in a range of 1% to 10%, and a mass percentage of the hydrogen peroxide in the main etchant is in a range of 4% to 10%.

2. The etchant for a copper-molybdenum film layer as claimed in claim 1, wherein the chelating agent is a first organic acid.

3. The etchant for a copper-molybdenum film layer as claimed in claim 2, wherein the first organic acid is selected from at least one of iminoacetic acid, ethylenediaminetetraacetic acid, citric acid, malic acid, acetic acid, succinic acid, tartaric acid, gluconic acid, and hydroxyacetic acid.

4. The etchant for a copper-molybdenum film layer as claimed in claim 1, wherein the first inorganic acid is selected from at least one of sulfuric acid, nitric acid, phosphoric acid, and hydrochloric acid.

5. The etchant for a copper-molybdenum film layer as claimed in claim 1, wherein a pH value of the etchant is in a range of 4-5.

6. The etchant for a copper-molybdenum film layer as claimed in claim 1, wherein the main etchant further comprises a buffering agent and a stabilizing agent, a mass percentage of the buffering agent in the main etchant is in a range of 0.5% to 5%, and a mass percentage of the stabilizing agent in the main etchant is in a range of 0.5% to 5%.

7. The etchant for a copper-molybdenum film layer as claimed in claim 6, wherein the mass percentage of the buffering agent in the main etchant is in a range of 0.5% to 2%, and the mass percentage of the stabilizing agent in the main etchant is in a range of 0.5% to 2%.

8. The etchant for a copper-molybdenum film layer as claimed in claim 6, wherein the buffering agent comprises at least one of acetic acid, sodium acetate, sodium hydrogen phosphate, and sodium borate.

9. The etchant for a copper-molybdenum film layer as claimed in claim 6, wherein the stabilizing agent comprises at least one of diethylamine pentaacetic acid, sodium silicate, magnesium chloride, tartaric acid, and trisodium phosphate.

10. The etchant for a copper-molybdenum film layer as claimed in claim 1, wherein the etchant further comprises an auxiliary etchant, and the auxiliary etchant comprises second organic acid and/or second inorganic acid, an inhibitor, and water.

11. The etchant for a copper-molybdenum film layer as claimed in claim 10, wherein a mass percentage of the second organic acid and/or the second inorganic acid in the auxiliary etchant is in a range of 0% to 20%, and a mass percentage of the inhibitor in the auxiliary etchant is in a range of 2% to 5%.

12. The etchant for a copper-molybdenum film layer as claimed in claim 11, wherein the mass percentage of the second organic acid and/or the second inorganic acid in the auxiliary etchant is in a range of 4% to 10%, and the mass percentage of the inhibitor in the auxiliary etchant is in a range of 3% to 4%.

13. The etchant for a copper-molybdenum film layer as claimed in claim 10, wherein the inhibitor is an azole compound.

14. The etchant for a copper-molybdenum film layer as claimed in claim 13, wherein the azole compound is selected from at least one of substituted or unsubstituted triazole, substituted or unsubstituted benzotriazole, substituted or unsubstituted imidazole, substituted or unsubstituted benzimidazole, substituted or unsubstituted pyrazol, substituted or unsubstituted benzopyrazole, substituted or unsubstituted thiazole, and substituted or unsubstituted benzothiazole.

15. The etchant for a copper-molybdenum film layer as claimed in claim 13, wherein the azole compound is selected from at least one of benzotriazole, hydroxybenzotriazole, methylbenzotriazole, aminotriazole, thiazole, and phenylthiazole.

16. An etching method for a copper-molybdenum film layer, wherein the etching method comprises:
providing a substrate, wherein a copper-molybdenum film layer is formed on the substrate, a patterned photoresist layer is formed on the copper-molybdenum film layer, and the copper-molybdenum film layer comprises a molybdenum film layer and a copper film layer disposed on a side of the molybdenum film layer that faces away from the substrate;
providing a main etchant, and etching, using the main etchant, the copper-molybdenum film layer shielded by the patterned photoresist layer, wherein the main etchant comprises hydrogen peroxide, a chelating agent, a first inorganic acid, and water, a mass percentage of the chelating agent in the main etchant is in a range of 2% to 10%, a mass percentage of the first inorganic acid in the main etchant is in a range of 1% to 10%, and a mass percentage of the hydrogen peroxide in the main etchant is in a range of 4% to 10%; and
peeling off the patterned photoresist layer.

17. The etching method for a copper-molybdenum film layer as claimed in claim 16, wherein the step of etching, using the main etchant, the copper-molybdenum film layer shielded by the patterned photoresist layer further comprises steps of:
continuously detecting a content of copper ions in the main etchant; and
adding an auxiliary etchant to the main etchant when the content of the copper ions in the main etchant reaches a threshold, wherein the auxiliary etchant comprises: second organic acid and/or second inorganic acid, an inhibitor, and water, wherein a mass percentage of the second organic acid and/or the second inorganic acid in the auxiliary etchant is in a range of 0% to 20%, a mass percentage of the inhibitor in the auxiliary etchant is in a range of 2% to 5%, and a mass of the added auxiliary etchant is in a range of 4% to 10% of a mass of the etchant before the addition.

18. The etching method for a copper-molybdenum film layer as claimed in claim 17, wherein the threshold comprises at least three sub-thresholds.

19. The etching method for a copper-molybdenum film layer as claimed in claim 18, wherein the at least three sub-thresholds are arranged in an arithmetic sequence.

20. The etching method for a copper-molybdenum film layer as claimed in claim 18, wherein a difference between two adjacent ones of the at least three sub-thresholds decreases with an increase in the sub-thresholds.
